(19) United States
(12) Patent Application Publication
(10) Pub. No.: US 2012/0125393 A1
(43) Pub. Date: May 24, 2012

(54) Photovoltaic Device and Method and System for Making Photovoltaic Device

(75) Inventor: Alex Austin, Santa Clara, CA (US)

(73) Assignee: MiaSole, Santa Clara, CA (US)

(21) Appl. No.: 12/951,711

(22) Filed: Nov. 22, 2010

(51) Int. Cl. H01L 31/05; B32B 38/04; B32B 37/10; B32B 38/00; B32B 37/12

(52) U.S. Cl. 136/244; 156/273.9; 156/273.7; 156/182; 156/379.7

(57) ABSTRACT

A method of making a photovoltaic device includes providing a first photovoltaic cell, placing a conductive interconnect in contact with an upper surface of the first photovoltaic cell, providing a thermoset adhesive over the conductive interconnect and over the upper surface of the first photovoltaic cell, and applying a current or voltage to the conductive interconnect to cure the thermoset adhesive such that the cured thermoset adhesive bonds the conductive interconnect to the upper surface of the first photovoltaic cell. The system used to make the device includes a conveyor, a wire applicator, a thermoset adhesive reservoir, a pressure roller in fluid communication with the reservoir, and first and second electrode rollers configured to apply a current or voltage to the conductive wire interconnect.

### BACKGROUND

The present invention relates to a photovoltaic device and a method and a system for making the photovoltaic device.

Many commercial photovoltaic (“PV”) modules are passive devices configured with a fixed arrangement of cells, interconnections and output characteristics. Cell to cell interconnections in such devices are made using a tab and string method by soldering copper strips between adjacent cells. Furthermore, many commercial photovoltaic modules are plagued with limitations relating to their manufacture, installation and operation.

### SUMMARY

According to one embodiment of the present invention, a method of making a photovoltaic device, may comprise: providing a first photovoltaic cell, placing a conductive interconnect in contact with an upper surface of the first photovoltaic cell, providing a thermoset adhesive over the conductive interconnect and over the upper surface of the first photovoltaic cell, and applying a current or voltage to the conductive interconnect to cure the thermoset adhesive such that the cured thermoset adhesive bonds the conductive interconnect to the upper surface of the first photovoltaic cell.

According to another embodiment of the present invention, a photovoltaic device, may comprise: a first photovoltaic cell, a second photovoltaic cell, and a conductive interconnect electrically connecting an upper surface of the first photovoltaic cell to a bottom surface of the second photovoltaic cell. The conductive interconnect may comprise at least one of a conductive serpentine wire or a conductive wire mesh and a cured thermoset adhesive which bonds sides of the at least one of the serpentine wire or wire mesh to the upper surface of the first photovoltaic cell and to the bottom surface of the second photovoltaic cell.

According to another embodiment of the present invention, a system for assembling a photovoltaic device may comprise: a conveyor configured to convey a photovoltaic strip in a substantially horizontal direction, a wire applicator configured to place one of a plurality of conductive wire interconnects in contact with an upper surface of the photovoltaic strip, a thermoset adhesive reservoir, a pressure roller in fluid communication with the reservoir, the pressure roller configured to supply the thermoset adhesive to outer surfaces of the conductive wire interconnect in contact with an upper surface of the photovoltaic strip, and first and second electrode rollers configured to apply a current or voltage to the conductive wire interconnect such that the thermoset adhesive is capable of curing.

It is to be understood that both the foregoing general description and the following detailed description are exemplary and explanatory only, and are not restrictive of the invention as claimed.

### BRIEF DESCRIPTION OF THE DRAWINGS

The features, aspects, and advantages of the present invention will become apparent from the following description, appended claims, and the accompanying exemplary embodiments shown in the drawings, which are briefly described below.

FIG. 1 is a flow chart showing a process for making a photovoltaic device according to one embodiment of the present invention.

FIGS. 2A and 2B are respective side and top view of a diagram of the system for making a photovoltaic device with a PV strip approaching the apparatus according to one embodiment of the present invention.

FIG. 2C shows a highly simplified schematic diagram of a top view of a modular sputtering apparatus that can be used to manufacture the PV strip.

FIGS. 3A and 3B are respective side and top view of a diagram of the system for making a photovoltaic device with the PV strip being laminated to an interconnect in the apparatus of FIGS. 2A and 2B.

FIG. 4 is a top view showing an interconnect according to an embodiment of the present invention.

FIG. 5 is a top view shown an interconnect according to another embodiment of the present invention.

FIG. 6 is a top view of a first PV cell after the thermoset adhesive has been cured according to the embodiment of FIG. 3B and the PV strip has been cut into PV cells.

FIG. 7 is a top view of the photovoltaic device after the second photovoltaic cell has been connected to the first PV cell.

FIGS. 8A-8D are side cross sectional views of the photovoltaic cells at different stages of interconnection and lamination according to the embodiment of the invention.

FIG. 9 is a top schematic view of the method for making a photovoltaic device according to another embodiment of the present invention

FIGS. 10A-10B are side cross sectional views of the photovoltaic cells at different stages of interconnection and lamination according to another embodiment of the invention.

FIG. 11 is a top view of the photovoltaic device after the thermoset adhesive has been cured according to the another embodiment.

FIG. 12 is a top view of the photovoltaic device after the second photovoltaic cell has been added according to the another embodiment.

### DETAILED DESCRIPTION

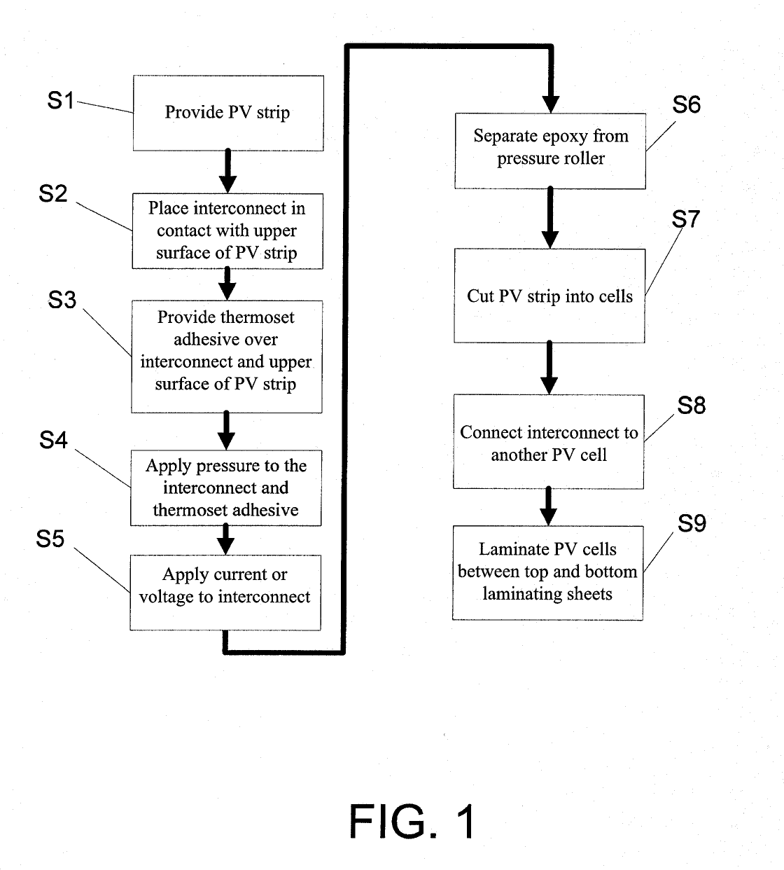

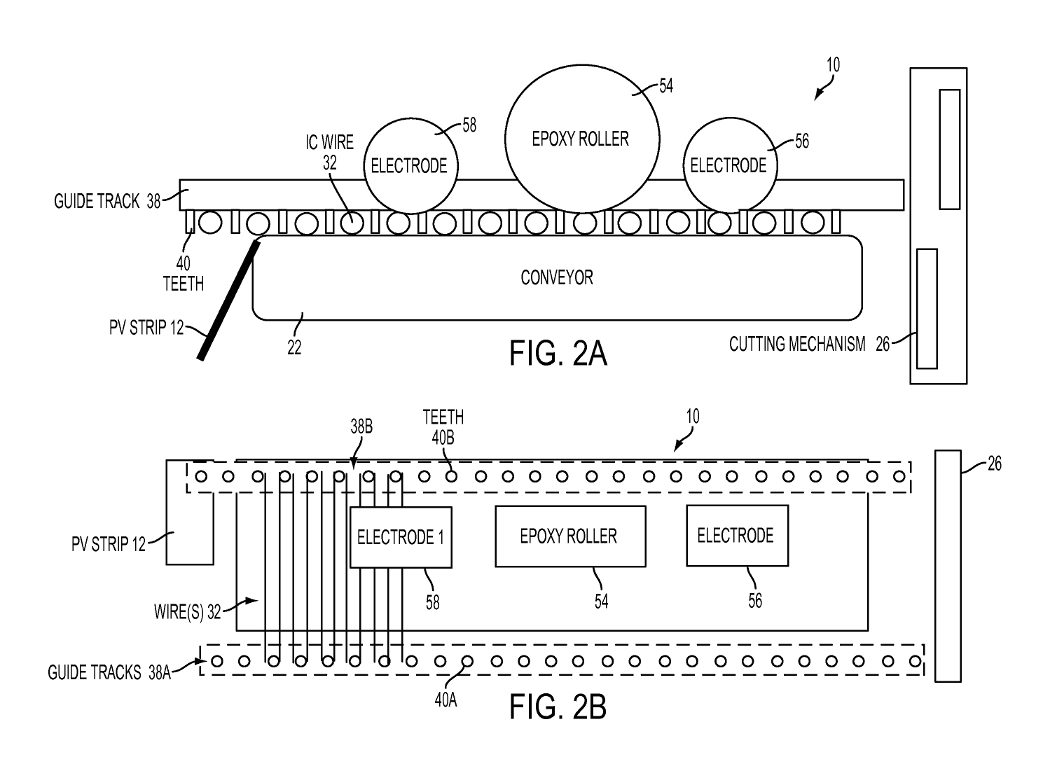

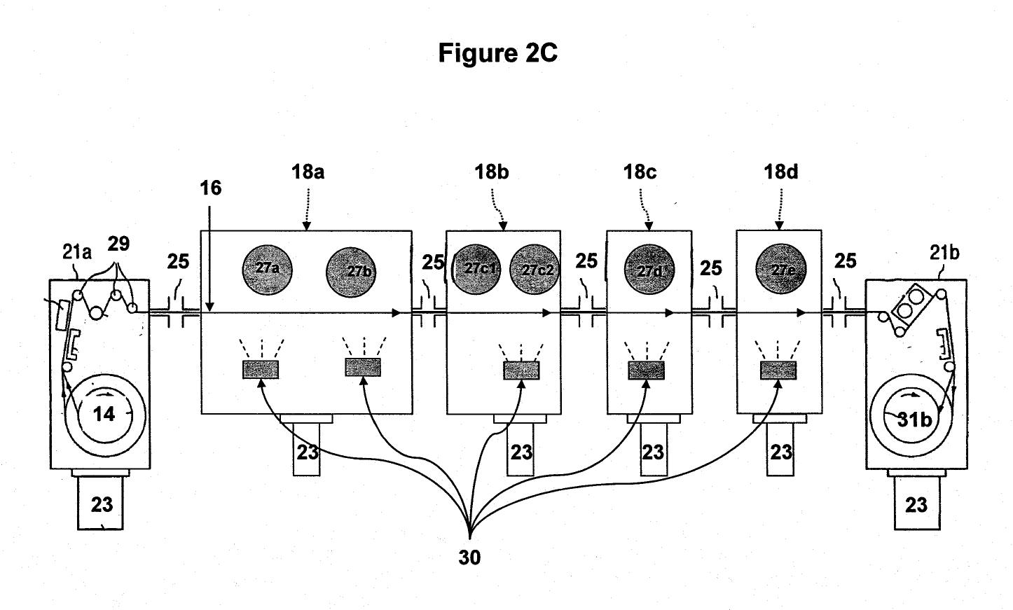

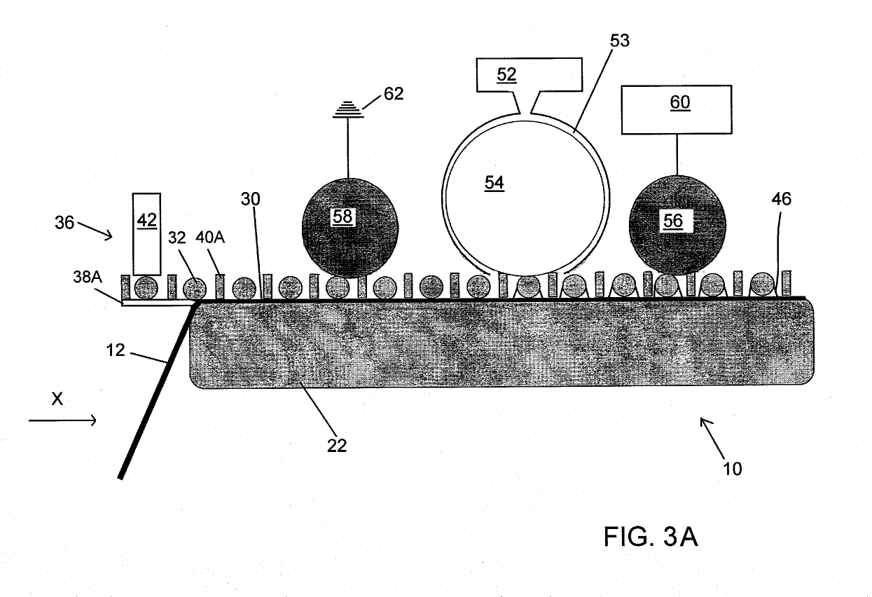

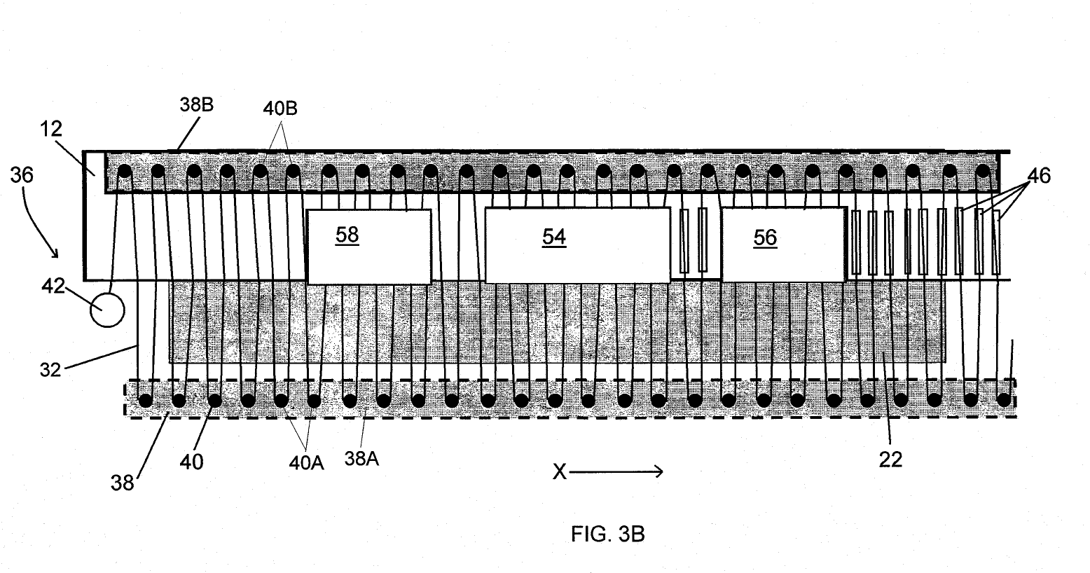

FIG. 1 is a flow chart showing the process for making a photovoltaic (“PV”) device while FIGS. 2A and 3A, 2B and 3B, respectively, show the respective side and top views of the apparatus 10 used for making the PV device. The process or method may comprise the step of providing a PV strip 12 in step S1. Preferably, the PV strip 12 comprises a flexible photovoltaic strip 12, such as a strip shaped flexible photovoltaic web, which will be cut into plural photovoltaic cells after attachment of an interconnect, as will be described in more detail below. It should be noted that the present invention is not limited to using a PV strip 12 which is later cut into PV cells, and discreet PV cells may be used instead of the strip 12.

In one non-limiting embodiment shown in FIG. 2C, to form the photovoltaic strip 12, a roll of flexible substrate web 16 may be unrolled from a spool 14 in an input module 21a. The substrate web 16 may comprise any suitable substrate material, such as plastic, metal (e.g., steel, titanium, aluminum, etc.), etc. The flexible substrate web 16 is provided into at least one deposition chamber 18 (e.g., plural chambers 18a-18d for example) to form the PV strip 12. The number of deposition chambers or process modules 18 may be varied to match the requirements of the device that is being produced. Each module has a pumping device 23, such as vacuum pump, for example a high throughput turbomolecular pump, to provide the required vacuum and to handle the flow of process gases during the sputtering operation. The modules are connected together at slit valves 25, which contain very narrow low conductance isolation slots to prevent process gases from mixing between modules. These slots may be separately pumped if required to increase the isolation even further. Other module connectors may also be used. Alternatively, a single large chamber may be internally segregated to effectively provide the module regions, if desired. Each respective sputtering chamber may be used to deposit at least one layer of the PV strip 12. For example, chamber 18a containing one or more sputtering targets 27a, 27b may be used to deposit a bottom electrode, such as a molybdenum or its alloy layer, over the substrate web 16. Chamber 18b containing one or more sputtering targets 27c1, 27c2, may be used to deposit at least one absorber layer, such as a p-type copper indium gallium selenide (CIGS) layer over the bottom electrode layer. Chamber 18c containing one or more sputtering targets 27d may be used to deposit at least one window layer, such as a n-type CdS layer, over the absorber layer. Chamber 18d containing one or more sputtering targets 27e may be used to deposit least one transparent upper electrode layer, such as a transparent conductive oxide, for example, zinc oxide, aluminum zinc oxide, and/or indium tin oxide, etc., over the window layer, as described in U.S. Pat. No. 7,544,884 and U.S. application Ser. No. 12/379,428 filed Feb. 20, 2009, incorporated herein by reference in their entirety. The upper surface of the PV strip 12 comprises the conductive material of the one of the electrodes (e.g., the upper transparent electrode) of the PV cells that will formed when the strip 12 is cut into PV cells. Other PV materials, such as silicon, CdTe, III-V materials, etc. may be used instead of CIGS and CdS. The web substrate 16 is moved throughout the machine by rollers 29 or other devices. Each chamber may include a back side heater 30 for heating the substrate 16. Deposition methods other than sputtering, such as CVD, plating, evaporation, etc. may also be used to deposit one or more layers. A rigid or semi-rigid substrate may be used instead of the flexible substrate web 16.

The PV strip 12 may be rolled up into a roll on an optional output spool 31b in an output module 21b shown in FIG. 2C. The roll may then be transferred to the apparatus shown in FIG. 2A and fed to the conveyor 22. Alternatively, the output module 21b may be omitted and the PV strip 12 may be fed directly from chamber 18d in FIG. 2C to the conveyor 22 shown in FIG. 2A. As shown in FIGS. 3A and 3B, the conveyor 22 is configured to convey the photovoltaic strip in a given direction, such as a substantially horizontal direction (“X”).

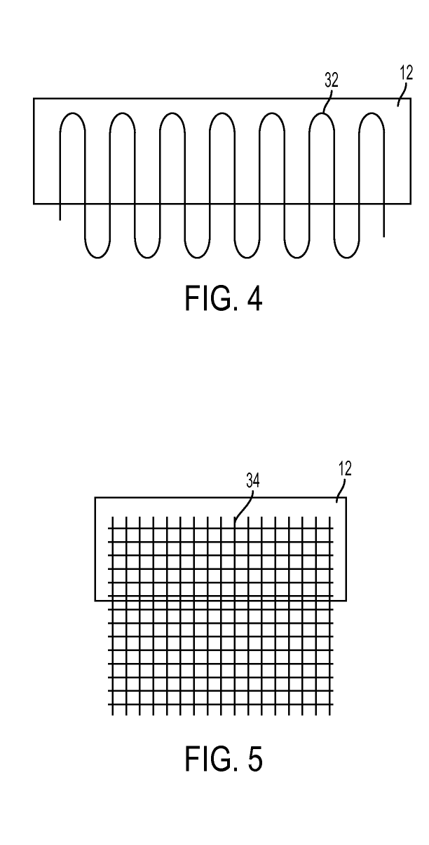

In step S2, a conductive interconnect 28 may be placed in contact with an upper surface 30 of the PV strip 12 that will be later cut to form at least a first photovoltaic cell 12′ described below. The step of placing the conductive interconnect in contact with the upper surface of the photovoltaic strip 12 may comprise placing the conductive interconnect 28 on the upper surface of the strip 12 while the strip 12 is moving. The interconnect 28 preferably comprises an electrically conductive material which will be used to interconnect at least two PV cells. Preferably, the interconnect 28 comprises one or more electrical conductors which act as both current collector(s) from the upper surface of the first PV cell 12′ and to electrically interconnect the first PV cell 12′ to the second PV cell 12″ as will be described below. An example of a collector-connector is described in U.S. application Ser. No. 11/451,616 filed on Jun. 13, 2006 and incorporated herein by reference in its entirety. Preferably, the interconnect 28 comprises at least one of an electrically conductive serpentine wire 32, as shown in FIG. 4, or an electrically conductive wire mesh 34, as shown in FIG. 5. A serpentine wire 32 has a sinuous shape, preferably in a shape of repeating, connecting “M” or “W” with curved edges. Other interconnect shapes may also be used, such as a plurality of separate electrically conductive wires. In one embodiment comprising the conductive serpentine wire 32 of FIG. 4, the conductive wire may be unrolled from a roll on a spool and then weaved or bent into the serpentine shape while the wire is moving. For example, the wire may be weaved or bent into a serpentine shape by any suitable apparatus, such as the apparatus described in U.S. application Ser. No. 12/052,476 filed on Mar. 20, 2008, incorporated herein by reference in its entirety. Preferably, as shown in FIGS. 2A and 2B, the moving wire 32 is weaved into a serpentine shape while the PV strip is approaching the apparatus 10. Then, while the serpentine wire 32 is still moving, the wire is placed in contact with the upper surface of the moving photovoltaic strip 12, and after the PV strip 12 is fed into the apparatus 10, as shown in FIGS. 3A and 3B. Thus, the wire 32 is bent or weaved into a serpentine shape and placed in contact with the PV strip in the same apparatus 10.

FIGS. 3A-3B illustrate one non-limiting method of placing the serpentine conductive wire 32 interconnect 28 of FIG. 4 in contact with an upper surface of the PV strip 12. A wire applicator or feeding mechanism 36 may include a wire guide or feeding mechanism 42 (e.g., a guiding head on a robotic arm or other movable and dispensing mechanism similar to a sewing machine feeding mechanism) which weaves or winds the wire 32 from a roll around offset teeth 40 (e.g., 40A, 40B) located on respective two parallel guide tracks 38 (e.g., 38A, 38B) to give the wire 32 its serpentine shape. The wire 32 is weaved wound around one tooth 40A on the first track 38A, then around adjacent offset tooth 40B on the second track, then around the next tooth 40A on the first track, etc. The guide tracks 38A, 38B are located above the conveyor 22 and the teeth 40A, 40B may point toward (i.e., down) or away (i.e., up) from the conveyor 22. FIG. 3A shows the top view of the apparatus with the wire 32 provided on the teeth 40A, 40B on the guide tracks 38A, 38B and the PV strip 12 moving on the conveyor 22 in a space between the guide tracks 38A, 38B and the conveyor 22. The wire 32 is held in place by the tension of the wire as it is snaked around the teeth 40.

Alternatively, the conductive interconnect may be a wire mesh 34 shown in FIG. 5. The wire mesh may be applied by unrolling the wire mesh from a roll on a spool and inserting the teeth 40 into the gaps adjacent to the sides of the wire mesh such that the teeth pull the wire mesh along the guide tracks 38.

In step S3 of FIG. 1, a thermoset adhesive 46 may be provided over the conductive interconnect 28 and over the upper surface of the photovoltaic strip 12 after the interconnect 28 and the PV strip 12 are provided over the conveyor 22, as shown in FIGS. 3A and 3B. The thermoset adhesive may be an electrically insulating, wet curable epoxy. As seen in FIG. 3A, to provide the thermoset adhesive 46, a thermoset adhesive reservoir 52 is used in conjunction and in fluid communication with a pressure roller 54. The reservoir 52 may comprise a die slot reservoir located above the pressure roller 54. The reservoir 52 is configured to deliver a uniform coating of the thermoset adhesive around the pressure roller onto the wire interconnect 28 via a channel 53 surrounding roller 54. The pressure roller 54 is configured to supply the thermoset adhesive 46 to the outer surfaces of the conductive wire interconnect 28 in contact with the upper surface of the PV strip 12 by flowing the adhesive around the pressure roller 54 onto the at least one of the serpentine wire 32 or wire mesh 34 interconnect 28.

In step S4, pressure is applied to the interconnect 28 and thermoset adhesive 46 by the pressure roller 54 to press the interconnect 28 into the upper surface of the PV strip 12. The step S4 of applying pressure may comprise rolling the pressure roller 54 over the thermoset adhesive 46 and the at least one of the serpentine wire 32 or wire mesh 34 to force a majority of the thermoset adhesive 46 out from a space between the at least one of the serpentine wire 32 or wire mesh 34 and the upper surface of the PV strip 12, such that the at least one of the serpentine wire 32 or wire mesh 34 directly, physically contacts the upper surface of at least one photovoltaic in the PV strip 12. Roller 54 is located between the wire guide tracks 38A, 38B in the direction perpendicular to the conveyor 22 movement direction.

In step S5 of FIG. 1, a current or voltage is applied to the conductive interconnect 28 to cure the thermoset adhesive 46 such that the cured thermoset adhesive bonds the conductive interconnect 28 to the upper surface of the PV strip 12. This step involves the application of the current or voltage to the interconnect 28 via first and second electrically conductive electrode rollers 56 and 58 in electrical contact with the conductive interconnect 28. The first and second electrode rollers 56 and 58 apply a current or voltage sequentially to the conductive interconnect 28 to generate heat in the interconnect (e.g., similar to an incandescent light bulb filament). The heat generated in the interconnect 28 cures the thermoset adhesive 46 in contact with the interconnect. To this end, the first and second electrode rollers are electrically conductive, and the first electrode roller 56 is connected to a voltage or current source 60 and the second electrode roller is connected to ground 62. As can be seen, the pressure roller 54 is placed between the first electrode roller 56 and the second electrode roller 58 in a traveling direction (X) of the conveyor 22 and PV strip 12. Of course, the ground and voltage or current source may be switched. When cured, the thermoset adhesive 46 bonds the sides of the at least one of the serpentine wire 32 or wire mesh 34 to the upper surface of the PV strip 12, as seen in FIGS. 3A and 3B.

According to one embodiment of the present invention, the steps of placing the conductive interconnect 28 in contact with the upper surface of the PV strip 12, providing the thermoset adhesive 46, and applying the current or voltage occur while the photovoltaic strip 12 is moving on the conveyor 22 past the pressure roller 54 and the first and second electrode rollers 56 and 58.

In step S6, the cured thermoset adhesive 46 is separated from the pressure roller 54 due to the rotation of the roller 54. The pressure roller 54 may comprise a smooth, insulating material that has a different value of thermal expansion coefficient from that of the cured form of the thermoset adhesive 46. This allows separation of the cured adhesive 46 from the pressure roller 54 due to the difference in the values of the coefficients of thermal expansion of the cured adhesive and the insulating pressure roller material.

In step S7, the PV strip 12 connected to the interconnect 28 is cut into a plurality of PV cells 12′ and 12″ by a cutting mechanism 26. The cutting mechanism may be any suitable cutting device, such as a blade with a cutting edge, a punch and die set, or the like. The cutting mechanism 26 may be located at the end of the conveyor 22 in apparatus 10 as shown in FIGS. 2A and 2B. Alternatively, the cutting mechanism 26 may be located separately from apparatus 10, and the PV strip 12 with the bonded interconnect 28 may be delivered manually or automatically from apparatus 10 to the cutting mechanism. The cutting mechanism 26 cuts the PV strip 12 and the interconnect 28 in a direction perpendicular to the PV strip elongation/movement direction to form a plurality of PV cells 12′, 12″. The resulting first PV cell 12′ with the interconnect 28 attached to upper electrode 48 of cell 12′ using the cured thermoset adhesive 46 is shown in top view in FIG. 6. As can be seen in FIG. 6, the first part of the interconnect 28 that is bonded to one surface of the first PV cell 12′ acts as a current collector because the interconnect wire or mesh contacts a majority of one electrode (e.g., the upper electrode 48) of the first PV cell 12′. The second part of the interconnect 28 that is not bonded to the PV cell 12′ hangs off the edge of the PV cell 12′ and will be used to connect the first PV cell 12′ to the second PV cell 12″ as shown in FIG. 7.

In step S8 of FIG. 1, the second portion of the conductive interconnect 28 is connected to a second photovoltaic cell 12″ such that the first and the second photovoltaic cells 12′ and 12″ are electrically connected in series. The second photovoltaic cell 12″ may be similar to the first photovoltaic cell 12′. For example, the second photovoltaic cell 12″ may comprise another portion cut from the PV strip 12 after the interconnect 28 is bonded to the PV strip. Alternatively, the second PV cell 12″ may be cut from a different PV strip than the first PV cell 12′. The second photovoltaic cell 12″ is placed on the second portion of the interconnect 28 hanging off the edge of the first PV cell 12′ such that an electrode on the lower surface of the second photovoltaic cell 12″ electrically contacts the second portion of the interconnect 28 as shown in FIG. 7. The PV cells 12′ and 12″ may be interconnected in a separate apparatus from the apparatus 10. For example, the PV cells may be interconnected in a separate laminator apparatus (not shown for clarity). Any suitable transfer mechanism, such as robot arm or one or more conveyors may be used to transfer the PV cells from the apparatus 10 to the laminator apparatus.

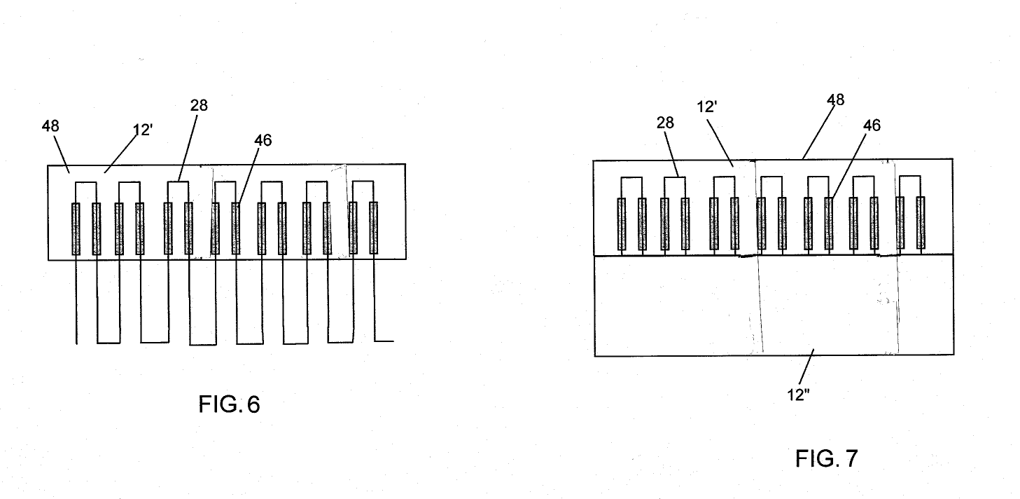

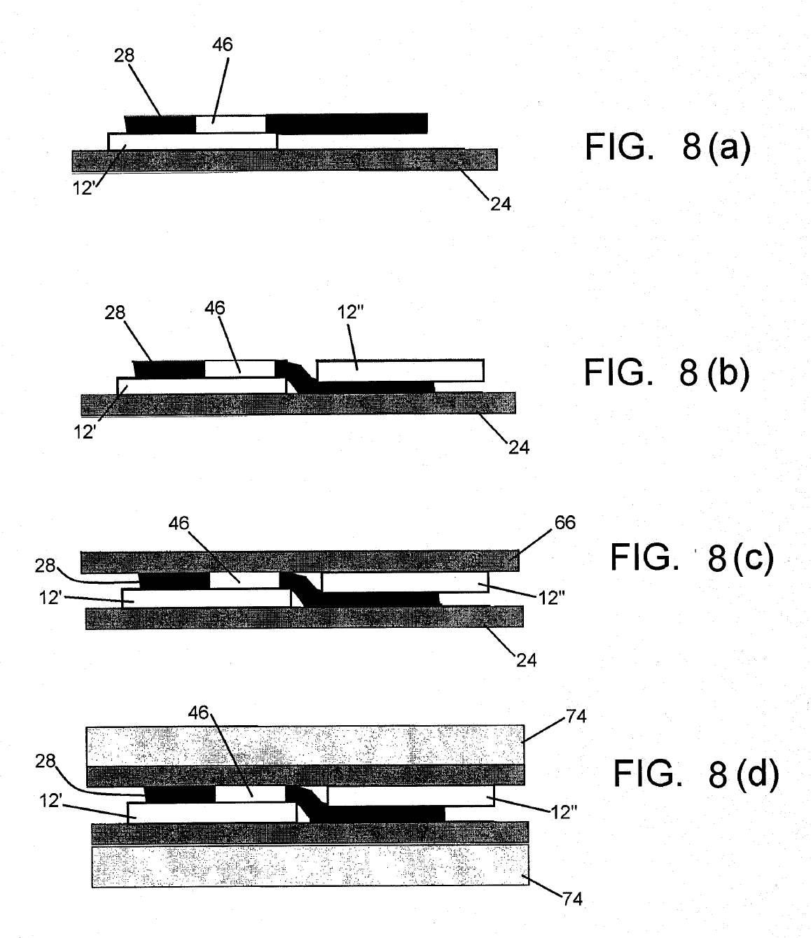

In step S9 of FIG. 1, the interconnected photovoltaic cells 12′, 12″ may be laminated between two glass and/or polymer sheets or panels in the laminator apparatus as shown in FIGS. 8A-8D. As shown in FIG. 8A, a robotic arm with a vacuum head or other suitable moving or transfer device may be used to place the first photovoltaic cell 12′ with the epoxy 46 connected interconnect 28 onto the bottom sheet or panel 24. Optionally, an adhesive coating may be applied to the bottom laminating sheet/panel 24 or photovoltaic cell 12′ before the cell 12′ is placed in contact with the sheet or panel 24. In one embodiment, shown in FIG. 8A, the first PV cell 12′ is placed on a polymer sheet 24. FIG. 8B shows the placement of the second photovoltaic cell 12″ on the second portion (e.g., the dangling wire or mesh portion) of the interconnect 28 which extends from the top of the first PV cell 12′. The bottom electrode of the second PV cell 12″ is placed on top of the second portion of the interconnect 28 to electrically interconnect the top, transparent electrode of the first PV cell 12′ to the bottom electrode of the second PV cell 12″. FIG. 8C shows the addition of the second laminating sheet 66 over the interconnected PV cells 12′, 12″. Sheet 66 may be a transparent polymer or plastic sheet. An adhesive coating (e.g., encapsulating materials) may be applied between the interconnected PV cells and sheet 66. FIG. 8D shows the addition of optional top and bottom glass panels 74 over the polymer sheets 24, 66. Panels 74 may be omitted if desired. The bottom sheet 24 and/or the bottom panel 74 may be referred to as a first module cover and the top sheet 66 and/or the top panel 74 may be referred to as a second module cover.

Using the method and system for making a photovoltaic device as outlined above, a photovoltaic device may be formed which comprises: a first photovoltaic cell 12′, a second photovoltaic cell 12″, and a conductive interconnect 28 electrically connecting an upper surface of the photovoltaic strip 12 to a bottom surface of the second photovoltaic cell 12″. The conductive interconnect 28 may comprise at least one of a conductive serpentine wire 32 (as shown in FIG. 4) or a conductive wire mesh 34 (as shown in FIG. 5). A cured thermoset adhesive 46 bonds the sides of the at least one of the serpentine wire 32 or wire mesh 34 to the upper surface of the first photovoltaic cell 12′. Optionally, an adhesive may also be applied to bond to the sides of the wire 32 or mesh 34 to the bottom surface of the second photovoltaic cell 12″. The at least one of the conductive serpentine wire 32 or the conductive wire mesh 34 directly and physically contact the upper surface of the first photovoltaic cell 12′ and the lower surface of the second photovoltaic cell 12″. The conductive interconnect may consist essentially of the at least one of the conductive serpentine wire 32 or the conductive wire mesh 34. Also, the photovoltaic device may lack an insulating polymer carrier sheet or ribbon which supports the at least one of the conductive serpentine wire 32 or the conductive wire mesh 34 in a space between the first and the second photovoltaic cells 12′ and 12″.

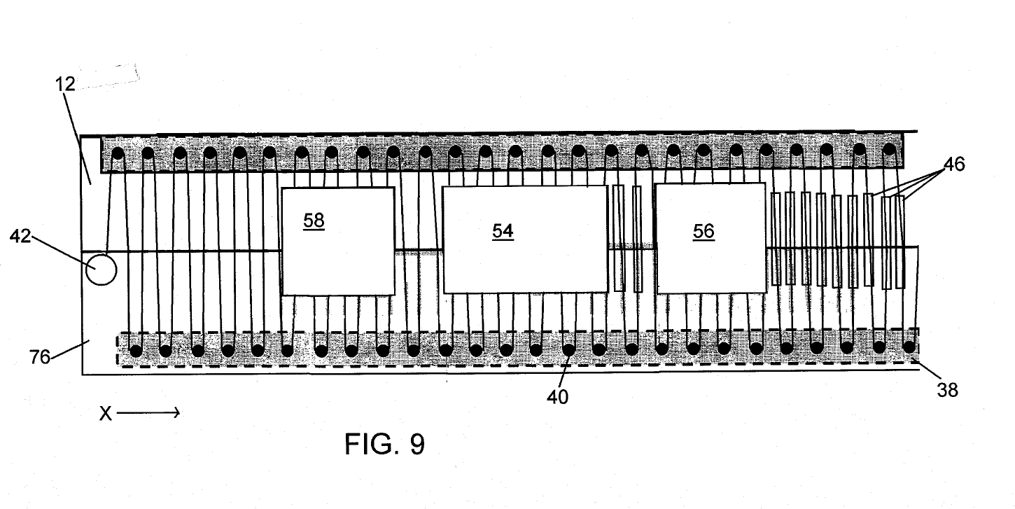

FIG. 9 shows an alternative method for making the photovoltaic device. The process or method may comprise the same steps as provided in FIG. 1 with the addition of a moving supporting material strip 76 being provided over the conveyor 22 along side of the PV strip 12. The supporting material strip 76 may be a flexible plastic or metal strip. The supporting material strip 76 may be provided from a spool and runs alongside (i.e., parallel to) the PV strip 12 on the conveyor 22. There may be a gap between the supporting material 76 and the first photovoltaic cell 12.

As shown in FIG. 9, the conductive interconnect 28 may be placed in contact with an upper surface 30 of the photovoltaic strip 12 as described in relation to FIG. 3A, but rather than having the second portion of the interconnect dangle from the edge of the PV strip 12, the second portion of the interconnect 28 is placed in contact with (i.e., on top of) the supporting material strip 76. The interconnect 28 may comprise at least one of a conductive serpentine wire 32 as seen in FIG. 4 or a conductive wire mesh 34 as seen in FIG. 5, and is placed on the moving photovoltaic strip 12 and the moving supporting material strip 76 in the same manner as described in the above embodiments.

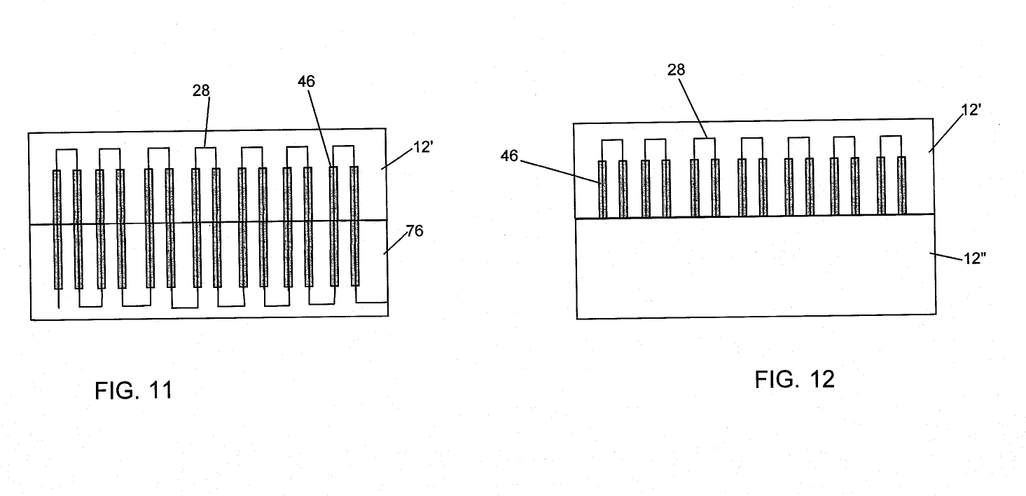

As described above with respect to FIGS. 3A and 3B and as shown in FIG. 11, the interconnect 28 is attached to both the PV strip 12 and the supporting material strip 76 with the thermoset adhesive 46 using the rollers 54, 56 and 58. The steps of placing the conductive interconnect 28 in contact with the upper surface of the photovoltaic strip 12 and the upper surface of the supporting material strip 76, providing the thermoset adhesive 46, and applying the current or voltage occur while the photovoltaic strip 12 and supporting material strip 76 are moving on the conveyor 22 past the pressure roller 54 and the first and second electrode rollers 56 and 58. The pressure roller 54 applies pressure to both first and second portions of the interconnect 28 located over the PV strip 12 and the supporting material strip 76, respectively.

The PV strip 12 and the supporting material strip 76 are then cut by the cutting mechanism into PV cells 12′. As shown in FIG. 11, a first PV cell 12′ includes a portion of the PV strip 12 and the supporting material strip 76 attached to each other by the interconnect 28. The interconnect 28 is attached to the strips 12 and 76 by the adhesive 46.

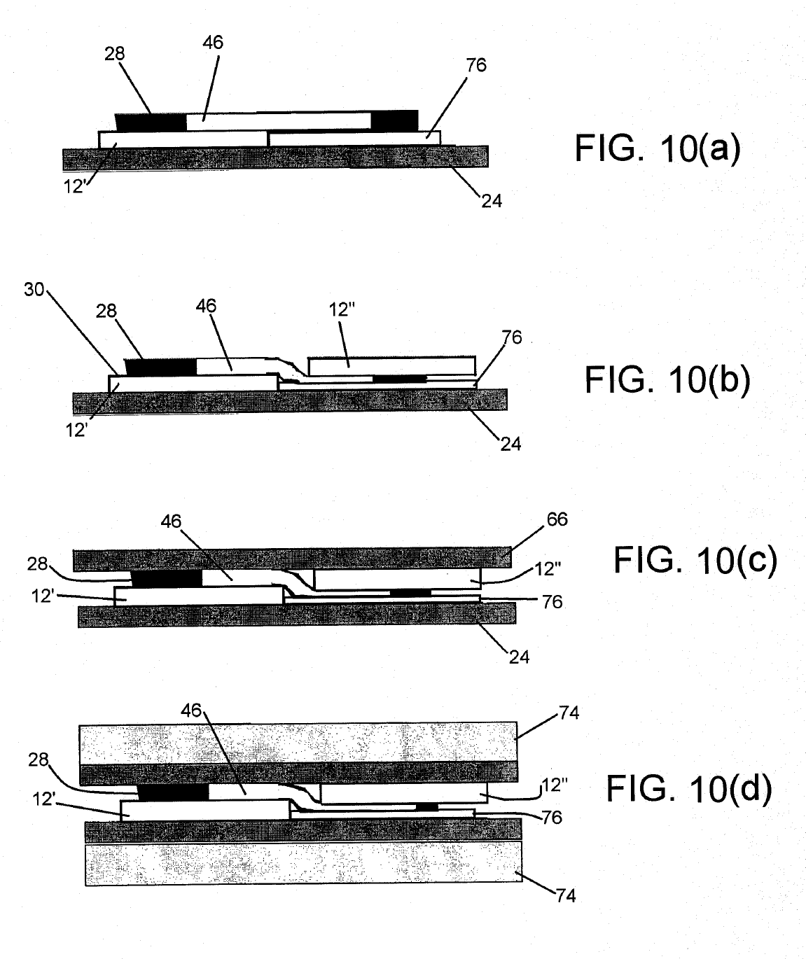

As shown in FIG. 10A, a robotic arm with a vacuum head or other suitable moving or transfer device may be used to place the first photovoltaic cell 12′ with the epoxy 46 connected interconnect 28 and supporting material 76 onto the bottom sheet or panel 24. Optionally, an adhesive coating may be applied to the bottom laminating sheet/panel 24 or photovoltaic cell 12′ before the cell 12′ is placed in contact with the sheet or panel 24. In one embodiment, shown in FIG. 10A, the first PV cell 12′ is placed on a polymer sheet 24. FIG. 10B shows the placement of the second photovoltaic cell 12″ on the second portion of the interconnect 28 which is located over the supporting material 76 and which extends from the top of the first PV cell 12′. The bottom electrode of the second PV cell 12″ is placed on top of the second portion of the interconnect 28 located on the support material 76 to electrically interconnect the top, transparent electrode of the first PV cell 12′ to the bottom electrode of the second PV cell 12″. FIG. 12 shows the top view of the device at this stage of the fabrication.

FIG. 8C shows the addition of the second laminating sheet 66 over the interconnected PV cells 12′, 12″. Sheet 66 may be a transparent polymer or plastic sheet. An adhesive coating may be applied between the interconnected PV cells and sheet 66. FIG. 8D shows the addition of optional top and bottom glass panels 74 over the polymer sheets 24, 66. Panels 74 may be omitted if desired.

While FIGS. 8A-8D and 10A-10D show the lamination of two PV cells 12′ and 12″, it should be understood that more than two cells may be laminated in series in this manner. For example, the second PV cell 12″ may also have a second interconnect located on its upper surface and extending from the edge of cell 12″. A third PV cell may be placed on top of the second interconnect, and so on. Thus, two or more (e.g., two to one hundred) PV cells may be interconnected in series prior to placing sheet 66 over the PV cells.

According to another embodiment of the present invention, the first and second photovoltaic cells may be a plurality of discrete, cut photovoltaic cells moving along the conveyor 22 instead of a continuous PV strip 12.

Besides those embodiments depicted in the figures and described in the above description, other embodiments of the present invention are also contemplated. For example, any single feature of one embodiment of the present invention may be used in any other embodiment of the present invention.

It is important to note that the construction and arrangement of system for making the photovoltaic device as shown in the various exemplary embodiments is illustrative only. Although only a few embodiments have been described in detail in this disclosure, those skilled in the art who review this disclosure will readily appreciate that many modifications are possible (e.g., placements of components, variations in sizes, dimensions, structures, shapes and proportions of the various elements, values of parameters, mounting arrangements, use of materials, colors, orientations, etc.) without materially departing from the novel teachings and advantages of the subject matter described herein. For example, elements shown as integrally formed may be constructed of multiple parts or elements, the position of elements may be reversed or otherwise varied, and the nature or number of discrete elements or positions may be altered or varied. The order or sequence of any process or method steps may be varied or re-sequenced according to alternative embodiments. The process steps may be run concurrently or consecutively with other process steps. Other substitutions, modifications, changes and omissions may also be made in the design, operating conditions and arrangement of the various exemplary embodiments without departing from the scope of the present invention.

Given the disclosure of the present invention, one versed in the art would appreciate that there may be other embodiments and modifications within the scope and spirit of the invention. Accordingly, all modifications attainable by one versed in the art from the present disclosure within the scope and spirit of the present invention are to be included as further embodiments of the present invention. The scope of the present invention is to be defined as set forth in the following claims.

What is claimed is:

1. A method of making a photovoltaic device, comprising:
providing a first photovoltaic cell;
placing a conductive interconnect in contact with an upper surface of the first photovoltaic cell;
providing a thermoset adhesive over the conductive interconnect and over the upper surface of the first photovoltaic cell; and
applying a current or voltage to the conductive interconnect to cure the thermoset adhesive such that the cured thermoset adhesive bonds the conductive interconnect to the upper surface of the first photovoltaic cell.

2. The method of claim 1, further comprising applying pressure to the interconnect and thermoset adhesive.

3. The method of claim 2, wherein the interconnect comprises at least one of a conductive serpentine wire or a conductive wire mesh.

4. The method of claim 3, wherein the step of applying pressure comprises rolling a pressure roller over the thermoset adhesive and the at least one of the serpentine wire or wire mesh to force a majority of the thermoset adhesive out from a space between the at least one of the serpentine wire or wire mesh and the upper surface of the first photovoltaic layer, such that the at least one of the serpentine wire or wire mesh directly, physically contacts the upper surface of the first photovoltaic cell, and the cured thermoset adhesive bonds sides of the at least one of the serpentine wire or wire mesh to the upper surface of the first photovoltaic cell.

5. The method of claim 4, wherein:
the thermoset adhesive is a wet curable epoxy;
the pressure roller comprises a smooth, insulating material; and
the step of providing the thermoset adhesive comprises flowing the epoxy around the pressure roller onto the at least one of the serpentine wire or wire mesh.

6. The method of claim 5, further comprising separating the cured epoxy from the pressure roller due to difference in a value of coefficient of thermal expansion of the cured epoxy and the insulating pressure roller material.

7. The method of claim 4, wherein the step of applying a current or voltage to the conductive interconnect comprises applying the current or voltage to the interconnect via first and second electrically conductive electrode rollers in electrical contact with the conductive interconnect.

8. The method of claim 7, wherein:
the step of placing the conductive interconnect in contact with the upper surface of the first photovoltaic cell comprises placing a first portion of the conductive interconnect on the upper surface of the first photovoltaic cell while the first photovoltaic cell comprises a portion of a photovoltaic strip which is moving; and
a second portion of the conductive interconnect extends past an edge of the photovoltaic strip.

9. The method of claim 8, wherein:
the photovoltaic strip comprises a strip of photovoltaic semiconductor p-n junction between a first electrode and a second transparent electrode;
the steps of placing the conductive interconnect in contact with the upper surface of the first photovoltaic cell, providing the thermoset adhesive, and applying the current or voltage occur while the photovoltaic strip is moving on a conveyor past the pressure roller and the first and second electrode rollers.

10. The method of claim 9, further comprising:
cutting the photovoltaic strip to separate the photovoltaic strip into a plurality of photovoltaic cells including the first photovoltaic cell and a second photovoltaic cell after the steps of placing the conductive interconnect, providing the thermoset adhesive and applying the current or voltage;
placing the separated first photovoltaic cell into a photovoltaic module over a first module cover such that the second portion of the conductive interconnect is exposed;
placing a lower surface of the second photovoltaic cell on the exposed second portion of the conductive interconnect to electrically connect the conductive interconnect to the second photovoltaic cell such that the first and the second photovoltaic cells are electrically connected in series;
placing an encapsulating material over the electrically connected first and second photovoltaic cells; and
laminating the electrically connected first and second photovoltaic cells between the first module cover and a second module cover in the photovoltaic module.

11. The method of claim 10, wherein the first and second photovoltaic cells comprise flexible cells formed on a flexible conductive substrate, the upper surface of the first photovoltaic cell comprises an upper electrode of the cell and the lower surface of the second photovoltaic cell comprises a lower electrode of the cell.

12. The method of claim 3, further comprising weaving a conductive wire into a serpentine shape while the wire is moving.

13. The method of claim 12, wherein the step of placing a conductive interconnect in contact with an upper surface of the first photovoltaic cell comprises placing the moving, weaved serpentine wire in contact with the upper surface of the first photovoltaic cell while the first photovoltaic cell comprises a portion of a photovoltaic strip which is moving.

14. A photovoltaic device, comprising:
a first photovoltaic cell;
a second photovoltaic cell; and
a conductive interconnect electrically connecting an upper surface of the first photovoltaic cell to a bottom surface of the second photovoltaic cell;
wherein the conductive interconnect comprises at least one of a conductive serpentine wire or a conductive wire mesh and a cured thermoset adhesive which bonds sides of the at least one of the serpentine wire or wire mesh to the upper surface of the first photovoltaic cell and to the bottom surface of the second photovoltaic cell.

15. The device of claim 14, wherein:
the adhesive is electrically insulating;
the at least one of the conductive serpentine wire or the conductive wire mesh directly, physically contacts the upper surface of the first photovoltaic cell;
the conductive interconnect consists essentially of the at least one of the conductive serpentine wire or the conductive wire mesh; and
the photovoltaic device lacks an insulating polymer carrier sheet or ribbon which supports the at least one of the conductive serpentine wire or the conductive wire mesh in a space between the first and the second photovoltaic cells.

16. A system for assembling a photovoltaic device, comprising:
a conveyor configured to convey a photovoltaic strip in a substantially horizontal direction;
a wire applicator configured to place a conductive wire interconnect in contact with an upper surface of the photovoltaic strip;
a thermoset adhesive reservoir;
a pressure roller in fluid communication with the reservoir, the pressure roller configured to supply the thermoset adhesive to outer surface of the conductive wire interconnect in contact with an upper surface of the photovoltaic strip; and
first and second electrode rollers configured to apply a current or voltage to the conductive wire interconnect such that the thermoset adhesive is capable of curing.

17. The system of claim 16, wherein the reservoir comprises a die slot reservoir located above the pressure roller, the reservoir configured to deliver a uniform coating of the thermoset adhesive around the pressure roller onto the wire interconnect.

18. The system of claim 16, wherein the pressure roller comprises a smooth, insulating material that has a different value of thermal expansion coefficient from that of a cured form of the thermoset adhesive which allows separation of the cured adhesive from the pressure roller due to the difference in the value of coefficient of thermal expansion of the cured adhesive and the insulating pressure roller material.

19. The system of claim 16, wherein the first and second electrode rollers are conductive, and wherein the first electrode roller is connected to a voltage or current source and the second electrode roller is connected to ground, and wherein the pressure roller is placed between the first electrode roller and the second electrode roller in a traveling direction of the conveyor.

20. The system of claim 16, wherein the wire applicator comprises guide track comprising teeth and a wire guide configured to guide a wire around the teeth on second conveyor to form a serpentine wire interconnect.
